(19) United States
(12) Patent Application Publication
(10) Pub. No.: US 2017/0362701 A1
(43) Pub. Date: Dec. 21, 2017

(54) CENTRAL SOURCE DELIVERY FOR CHEMICAL VAPOR DEPOSITION SYSTEMS

(71) Applicant: Veeco Instruments Inc., Plainview, NY (US)

(72) Inventors: Raymond C. Logue, Henderson, NV (US); Don N. Sirota, Poughkeepsie, NY (US); Karthik Karkala, Sayreville, NJ (US); Arindam Sinharoy, Furlong, PA (US)

(21) Appl. No.: 15/613,422

(22) Filed: Jun. 5, 2017

Related U.S. Application Data
(60) Provisional application No. 62/350,803, filed on Jun. 16, 2016.

(51) Int. Cl. C23C 16/448; C23C 16/455; C23C 14/56

(52) U.S. Cl. CPC C23C 16/448; C23C 14/56; C23C 16/45574

(57) ABSTRACT

According to embodiments, systems and methods are described herein that facilitate use of a Chemical Vapor Deposition (CVD) system continuously. The systems and methods shown herein include multiple precursor gas sources, and structures for independently connecting or disconnecting those sources for replacement. Furthermore, by providing user inputs for diluting the outputs of these multiple precursor gas sources, mixtures of precursor gas in carrier gas can be generated that have sufficiently low concentrations to be routed to a remove CVD system even at relatively low temperatures. Therefore, in embodiments many precursor gas sources, located remotely from the CVD chamber, can be independently operated and replaced as needed without interrupting a supply of precursor gas to the CVD chamber.

### TECHNICAL FIELD

The disclosure relates to chemical coating by decomposition of gaseous compounds, without leaving reaction products of surface material in the coating, such as chemical vapor deposition (CVD) and metalorganic chemical vapor deposition (MOCVD). In particular, various disclosed embodiments include precursor gas supplies that facilitate continuous functionality and operation of a vapor deposition system. Gas mixture generating systems generate the binary mixtures of solid, liquid or gaseous precursors in-situ, which is mixed with the carrier gas. This remotely located system provides multiple reactors with accurately premixed to desired concentration binary mixtures.

### BACKGROUND

Chemical vapor deposition (CVD) is a process that can be used to grow desired objects epitaxially. Examples of current product lines of manufacturing equipment that can be used in CVD processes include the TurboDisc®, MaxBright®, and EPIK™ family of MOCVD systems, manufactured by Veeco Instruments Inc. of Plainview, N.Y.

Numerous industries employ processes that require accurate delivery of gas mixtures comprising a gas of interest within the carrier gas. New processes raised substantially the requirements to the accuracy, repeatability and reproducibility of delivered gas of interest in the flowing gas mixture, where the gas of interest is typically of high purity and highly corrosive. Common examples of these processes are different types of CVD (chemical vapor deposition) processes in the semiconductor, compound semiconductor, fiber-optic, and other industries.

A number of process parameters are controlled, such as temperature, pressure and gas flow rate, to achieve a desired crystal growth in a CVD system. Different layers can be grown using varying materials and process parameters. For example, devices formed from compound semiconductors such as group III-V semiconductors typically are formed by growing successive layers of the compound semiconductor using metal organic chemical vapor deposition (MOCVD). In this process, the wafers are exposed to a combination of gases, typically including a metal organic compound as a source of a group III metal, and also including a source of a group V element (for example, arsenic or phosphorus) which flow over the surface of the wafer while the wafer is maintained at an elevated temperature. Generally, the metal organic compound and group V source are combined with a carrier gas which does not participate appreciably in the reaction as, for example, nitrogen or hydrogen. One example of a group III-V semiconductor is indium phosphide (InP), which can be formed by reaction of indium and phosphine or aluminum gallium arsenide (AlGa₁₋ₓAsₓ), which can be formed by the reaction of aluminum, gallium, and arsine. The reaction of the compounds form a semiconductor layer on a substrate having a suitable substrate. These precursor and carrier gases can be introduced by an injector block configured to distribute the gas as evenly as possible across the growth surface.

In order to provide proper ratios of the precursor gases, gas source systems are used in which a carrier gas is loaded with gaseous or aerosolized precursor material. For example, a carrier gas can be sparged through a liquid precursor material. In some such systems, this can be accomplished by positioning a dip tube in the liquid precursor material, and then routing the carrier gas such as nitrogen through the liquid. As the carrier gas passes through the liquid, it picks up a quantity of the precursor material. These types of systems are called “bubblers” due to the carrier gas bubbling through the liquid precursor. Typically, each bubbler includes enough liquid precursor to operate a CVD system for several hours. Likewise, in other systems, a solid precursor material can be sublimated into a carrier gas flow in a sublimator system.

Conventionally, carrier gas flow through the bubbler (or through the sublimater in case of the solid sources) is measured using a mass flow controller located upstream or downstream of the bubbler (or sublimator) to control the mass transfer rate of the precursor to the reactor. This is conventionally an open loop system, and for example in conventional EPI processes for generating single wafers, it provides wafer-to-wafer thickness uniformity on the order 1-2%. This approach is inaccurate and unrepeatable for several reasons, including instability of bubbler temperature and pressure, heat of vaporization effect, etc.

U.S. Pat. Nos. 6,116,080, 6,192,739, 6,199,423, 6,279,379 as well as Patent Application 2014/0060153 A1, all of which are assigned to Veeco Flow Technologies, disclose technique and electroacoustic binary mixture concentration sensor Piezocon® systems that provide a substantial improvement over above open loop system. Such systems are described in R. Logue et al., Deposition Rate Control During Silicon Epitaxy, Semiconductor International, Jul. 1, 2014. As described in that publication, improvements on the conventional system achieved by using certain piezoelectric concentration sensors can increase wafer-to-wafer thickness uniformity, such that deviations are less than about 0.15-0.20%.

CVD systems often require precursor inputs at a defined temperature or temperature range. Deviation from these defined temperatures can cause several problems. First, output from the bubblers or sublimators contains high enough concentrations of precursor gas that, if the temperature falls sufficiently, the precursor gas may condense. Second, the output from the bubblers or sublimators should be kept below pyrolyzation temperature until it is at or near the desired surface for deposition. Third, locating a high concentration vapor source remote from the reactor leads to the possibility of a pressure drop, causing adiabatic cooling of the flowing mixture and localized condensation. For this reason, conventionally, bubblers or sublimators for producing carrier gas and vapor mixtures have been kept in very close proximity to the CVD chamber, as routing precursor gas through tubing that is maintained within this specific temperature range is energy-intensive and the consequences of failure to maintain the necessary temperature can be severe.

U.S. Pat. No. 5,835,678 (“Li”) describes systems employing bubblers that have employed heated delivery lines and other devices to prevent the condensation of precursors that are reluctant to form vapors. These heaters can be used to extend the distance between the bubbler and the reactor. Such heaters require monitoring and constant power. Loss of power, a faulty temperature sensor, or other problems can cause undesirable buildup or settling out of the precursor material in the lines.

U.S. Pat. No. 8,486,191 (“Aggarwal”) describes multiple delivery paths for gas delivery to a reaction chamber. Each path contains a different gas, and the gases react only once they reach the chamber in a common mixing path. Aggarwal noted the benefits of reducing footprint of systems within the semiconductor fabrication industry. Aggarwal also describes the benefits of forming a desired concentration of precursor gas mixture well in advance of deposition.

U.S. Pat. No. 4,980,204 (“Fujii”) describes a gas supply system in which a gas flow rate through each vent pipe is made to be controllable individually by a flow controlling device. This can be used to create a uniform concentration of reactants in the reaction chamber.

None of these references, however, solve problems in the art such as maintaining continuous (or near-continuous) flow of reactant gas, from a bubbler source that can be positioned at a large distance from the reactor, and for providing that near-continuous flow of reactant gas at a variety of desired concentrations.

Replacement of a bubbler or sublimator can be time-intensive. Once the precursor source is consumed, any lines containing precursor gas must be purged, because many precursor gases are pyrophoric. Then the bubbler or sublimator itself can be replaced or refilled. Before reconnecting the bubbler or sublimator, however, a vacuum typically must be pulled in the lines, again to prevent damage that could be caused by the introduction of a pyrophoric material into air-filled lines. Even once reconnected to the lines, a bubbler or sublimator can take several hours of temperature conditioning before the precursor gas is at an appropriate temperature to provide precursor gas to a CVD system.

Furthermore, replacement of a reactor produces insufficiently accurate or repeatable deposition results. For example, in the U.S. Pat. No. 8,997,775 and US Patent application 20150167172 A1 the authors are recommending to use their methods for the low vapor pressure solid precursors, such as TrimethylIndium and Cyclopentadienil Magnesium. For reasonably chosen operating conditions for the GaN process of 17° C. and 900 torr, which prevent the condensation of the binary mixtures flowing through the concentration sensor, such as mentioned above Piezocon®, the accuracy and repeatability with Nitrogen as a carrier gas are shown in the table below.

| | Vapor | Concen- | Relative | Relative |
|---|---|---|---|---|
| | Pressure | tration at | Piezocon | Piezocon |
| | at 17° C., | 900 torr, | Accuracy, | Repeatability, |
| Precursor | torr | ppm | % | % |
| TrimethylIndium | 0.96 | 1067 | 14 | 1.9 |
| Cyclopentadienil | 0.02 | 23 | 535 | 71 |
| Magnesium | | | | |

According to ELMOS, TrimethylIndium vapor pressure can be approximately computed as

$${P}_{v} = {10}^{( 9.735 - \frac{2830}{T} )}$$

where T=290.15° K is the mixture condensation temperature in ° K (17° C.). After the substitution it can be determined that Pv=0.96 torr.
Similarly we can approximately compute the vapor pressure of Cyclopentadienil Magnesium using the formula

$${P}_{v} = {10}^{( 25.14 - 2.18 \times log ( T ) - \frac{4198}{T} )}$$

Substituting T=290.15° K we can compute that the vapor pressure at condensation temperature is Pv=0.02 torr.

The expected molar concentration is calculated as

$$MC = \frac{{P}_{v}}{P}$$

and converted to parts per million (ppm) by multiplying by 10⁶. Similar to other measuring devices, the performance of Piezocon® has some limits and this is especially affected at low concentration. In the Piezocon® manual is shown a way of computation of the expected accuracy and repeatability of the concentration measurement. Computed for both above precursors relative to measured concentration accuracy and repeatability with Nitrogen as a carrier gas are shown the table above. These parameters are computed only for the concentration sensor and do not include performance of all other components of the control system, such as proportional valves, pressure sensor, etc. As can be seen in the table above, estimated performance cannot be considered acceptable for the contemporary MOCVD or CVD processes and could be improved.

Furthermore, conventional processes require wide dynamic range of the precursor delivery. For example, process 0791 for the Propel HVM reactor requires TrimethylAluminum delivery in the range from 0.711 mg/min to 50.82 g/min, or about 70 times. Conventional tools include up to six independent reactors, therefore the required range for 6 reactors can vary up to 420 times. Existing delivery systems “on-demand” are designed as synchronous systems, meaning they are unable to satisfy required dynamic range because the contemporary controlling components, such as mass flow controllers, proportional valves, and other standard components, have acceptable accuracy and repeatability in the range of about 5-10 times their lowest setting. For the required wide dynamic range of the precursor delivery system, this accuracy range is insufficient.

Some systems attempt to overcome this shortcoming using either dilution or double-dilution architectures. Employing these approaches leads to a wasting of expensive precursors by directing substantial amounts of the binary mixture to the scrubber during the run.

In addition, typically for the best performance during the deposition it is required to have sharp interfaces for each precursor. However, in the above example for the 791 process the dynamic range is such that at 20° C. and 900 torr it will require the mass flow controller set points from 10.9 sccm to 779 sccm. At a mass flow rate of 10.9 sccm, the flow velocity will be on the order of 15 mm/s and at these flow rates reaching sharp interfaces is difficult. For reasonably sharp interfaces, the flow rate typically must be at least several hundred sccm.

Whenever in one of the bubblers/sublimaters the remaining amount of precursor becomes low, the reactor is stopped for the replacement of this bubbler/sublimater. Typically bubbler replacement is a time-consuming process of the reactor's downtime because it includes the following steps: multiple cycles of vacuum/purge of the bubbler's legs after closing the bubbler's manual valves for avoiding chemical reaction between the precursor and the water vapor in the air, removing the old bubbler and replacing it with the new one, repeating multiple cycles of vacuum/purge of the bubbler's legs, leak testing, stabilizing the bubbler's temperature at its operating condition and finally carefully opening the bubbler's manual valves preventing bubbler's splashing, which sometimes occurs when the bubbler's headspace pressure is above line pressure.

Recovery time after changing a bubbler or sublimator depends on the flow rate through the bubbler/sublimater, bubbler's or sublimater's headspace, flow velocity and the length of tubing, or other factors. Changing one precursor gas source or reactor affects not only the newly connected source or reactor but also previously running reactor due to the cross-talk. Conventionally, the only way for implementing a synchronous precursor delivery system for multiple reactors without negatively affecting the process has been to synchronize all the reactors, and purge out the mixture at the required flow rate until it reaches a desired concentration. As a rule, the reactors are not synchronized, however. Therefore, in unsynchronized systems, large quantities of time could be lost during bubbler or sublimator replacement.

When a carrier gas is flowing through a small bubbler, typically at the volumetric flow rates of over 5 LPM the carrier gas is picking up not only the vaporized precursor but also small micro droplets of liquid. They also undergo secondary vaporization inside the heated to higher temperature downstream lines, which creates unstable concentration of the precursor negatively affecting the process. If we feed the same source to multiple reactors, this problem will be substantially amplified.

### SUMMARY

Systems and methods are described herein that facilitate use of a CVD system continuously. The systems and methods shown herein include multiple precursor gas sources, and structures for independently connecting or disconnecting those sources for replacement. Use of multiple sources reduces the downtime associated with disconnecting and replacing a precursor gas source, which often requires several hours during which lines are vented, the precursor gas source is disconnected, a new precursor gas source is attached and heated to a desired operating temperature, and then the lines are re-purged before being provided with the output from the new precursor gas source. According to some embodiments, these replacement steps can be accomplished for one precursor gas source while another continues to provide precursor gas to the CVD system, resulting in an elimination of downtime related to changing out the precursor gas source.

By providing user inputs for diluting the outputs of these multiple precursor gas sources, mixtures of precursor gas in carrier gas can be generated that have sufficiently low concentrations to be routed to a remote CVD system even at relatively low temperatures. Therefore, in embodiments many precursor gas sources, located remotely from the CVD chamber, can be independently operated and replaced as needed without interrupting a supply of precursor gas to the CVD chamber. This prevents cluttering on the top of the tool, and generally makes use, repair, and maintenance of the tool less cumbersome.

According to one embodiment, a system for providing precursor gas includes a user interface comprising a plurality of carrier gas inputs, a primary precursor gas source configured to receive a carrier gas from one of the plurality of carrier gas inputs and produce a primary precursor gas mixture, an auxiliary precursor gas source configured to receive a carrier gas from one of the plurality of carrier gas inputs and produce an auxiliary precursor gas mixture, and an output configured to receive a precursor gas mixture by combining at least a portion of the primary precursor gas mixture, at least a portion of the auxiliary precursor gas mixture, and a carrier gas from at least one of the plurality of carrier gas inputs.

According to another embodiment, a method for continuous operation of a chemical vapor deposition system includes providing a carrier gas at a first user input and routing it to the inlet of a primary precursor gas source to generate a precursor gas mixture at an outlet of the primary precursor gas source, providing a carrier gas at a second user input and routing it to the inlet of an auxiliary precursor gas source to generate a precursor gas mixture at an outlet of the auxiliary precursor gas source, combining the precursor gas mixture of the primary precursor gas source and the precursor gas mixture of the auxiliary gas source to form a combined precursor gas mixture, mixing at least a portion of the combined precursor gas mixture with a carrier gas from a third user input to form a diluted precursor gas mixture that has a sufficiently low concentration that the precursor gas is fully soluble in the carrier gas above a temperature, and routing the diluted precursor gas mixture, at or above the temperature, to a remote chemical vapor deposition tool.

The above summary of the invention is not intended to describe each illustrated embodiment or every implementation of the present invention. The detailed description and claims that follow more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 is a flow diagram depicting two precursor gas sources configured to provide continuous supply of a precursor gas for chemical vapor deposition, according to an embodiment;

FIG. 2 is a diagram depicting a system of valves and lines that permit for selective removal or replacement of a precursor gas source during continuous operation of a reactor, according to an embodiment;

FIG. 3 is a diagram of a system for mixing and accumulating the output of the system of valves and lines of the embodiments shown in FIG. 2.

While embodiments are amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION OF THE DRAWINGS

According to embodiments, systems include at least a primary and an auxiliary precursor gas source. In embodiments, the precursor gas source can be either a bubbler or sublimator, though in the description provided before “bubbler” is used to refer to either of these, or any other precursor gas source, for convenience. One of ordinary skill in the art would understand that these precursor gas sources depend on a desired precursor gas, and are often interchangeable.

According to embodiments, systems include multiple bubblers that can be operated independently, and tubing or piping systems that can be disconnected from one or more of the bubblers without disrupting supply of the precursor gas. In this way, the need for downtime to change a bubbler is reduced or obviated. The tubing or piping systems can also be connected to additional inputs such that a sufficiently low precursor gas concentration within the carrier gas is created, and precursor gas can be routed from a location remote from the reactor chamber.

As described in more detail below, a precursor generation source, precursor gas conditioning, and precursor gas delivery subsystems can be provided to continuously deliver precursor gas mixture to a reactor housing or tool used in CVD systems. Because precursor gas mixture is generated and accumulated that has a relatively low concentration, it is not necessary to position the bubbler or other precursor gas source directly on the reactor chamber or tool itself. The ability to position precursor gas sources further from the reactor housing facilitates a smaller tool foot-print, and therefore the tighter cleanliness requirements associated with some semiconductor applications can be more easily met. Re-layout of the tool for serviceability can also be accomplished much more easily without the precursor gas source arranged on the tool itself. In embodiments, the system can facilitate scaling, or addition of more precursor to reactors. By enabling accumulation of multiple concentrations of precursor gas in carrier gas, reduced venting of precursor gas mixes is accomplished, and an improvement in run-to-run and tool-to-tool matching due to controlled and stable delivery of flux is possible.

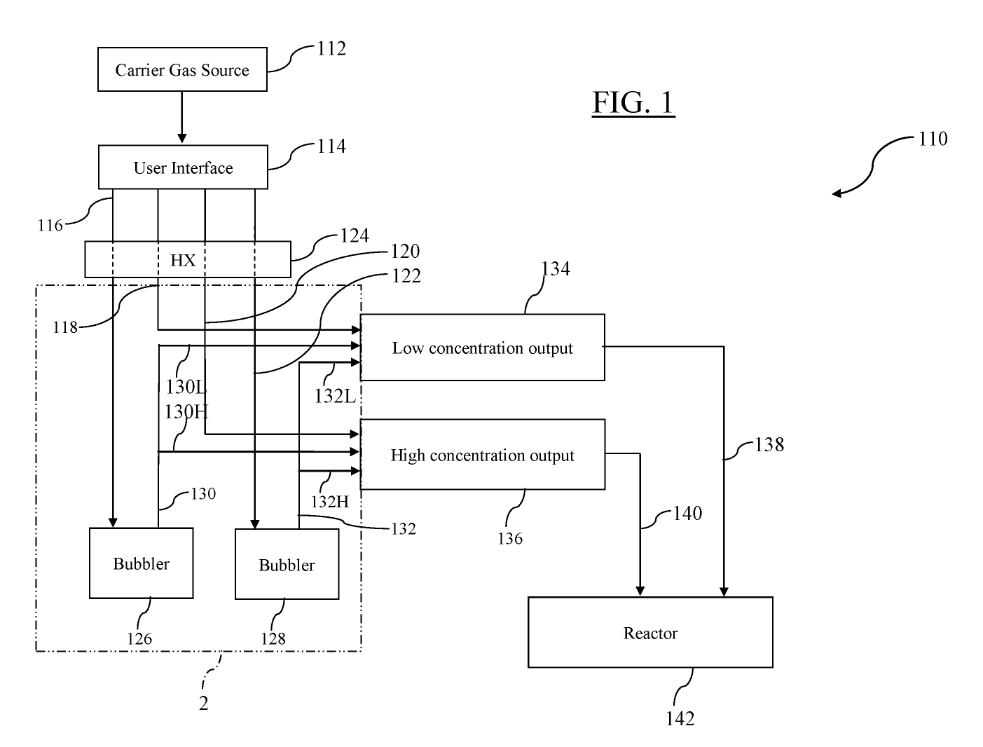

FIG. 1 depicts an embodiment of a system 110 for providing a precursor gas at a desired concentration for chemical vapor deposition. System 110 includes carrier gas source 112, which can be any carrier gas used to deliver precursor gas. For example, in embodiments carrier gas source 112 can be a pressurized source of hydrogen, nitrogen, or argon gas, in embodiments. In alternative embodiments various other inert or noble gases can be used as a carrier gas.

Carrier gas source 112 provides carrier gas to a user interface 114. Depending on the process there are different carrier gases and most commonly used in CVD processes are Nitrogen, Hydrogen, Argon, Helium, or others. User interface 114 is an interface that can be used either manually or automatically to adjust the amount of carrier gas that is delivered via each of a series of lines. For example, in the embodiment shown in FIG. 1, there are four lines (first input line 116, second input line 118, third input line 120, and fourth input line 122). These four input lines can receive more or less of the carrier gas, depending on the settings at user interface 114. In embodiments, such settings can be modified based upon feedback from sensors within the rest of system 110, as will be described in more detail below. Furthermore, various alternative embodiments may include a different number of input lines, depending on the desired number of precursor gas concentration(s) and bubblers, as described in more detail below.

First, second, third, and fourth input lines (116, 118, 120, and 122, respectively) pass through heat exchanger 124, in the embodiment shown in FIG. 1. Heat exchanger 124 can be used to ensure that the carrier gas flowing through the first through fourth input lines (116, 118, 120, and 122, respectively) is at a desired input temperature. In alternative embodiments, some or all of the first through fourth input lines (116, 118, 120, and 122, respectively) may not be routed through heat exchanger 124. Additionally or alternatively, one or more of the first through fourth input lines (116, 118, 120, and 122, respectively) can be routed through individual heat exchangers (not shown), such that each line can be controlled and set to a desired input temperature. In such embodiments, the temperature associated with each of the first through fourth input lines (116, 118, 120, and 122, respectively) can be independently set and monitored. In embodiments, controlled flow rate for each of the first through fourth input lines (116, 118, 120, and 122, respectively) can be set, whether using a single heat exchanger 124 or multiple heat exchangers, using user interface 114. User interface 114 can include regulators, flowmeters, shutoff valves, or other devices that can modify the throughput of the carrier gas at each of the input lines 116-122.

Carrier gas in the first through fourth input lines (116, 118, 120, and 122, respectively) that has passed through heat exchanger 124 can be used to generate precursor gas mixtures having a desired concentration and a desired temperature. The addition of precursor gas to the carrier gas is accomplished using a system of bubblers and piping.

In the embodiment shown in FIG. 1, first input line 116 is routed to primary bubbler 126. Primary bubbler 126 is an apparatus configured to create a mixture of carrier gas and precursor gas. In one embodiment, primary bubbler 126 comprises a quantity of liquid precursor material. The precursor material is a material that can be used in chemical vapor deposition. In embodiments, the precursor material can be pyrolyzable such that, when heated, epitaxial growth of a desired material can occur on a substrate.

Primary bubbler 126 can receive a carrier gas supply, which can be applied to a pressure regulator at its inlet in embodiment. Depending on the intended CVD process, there are different carrier gases used. Most commonly used in CVD processes are Nitrogen, Hydrogen, Argon, and Helium. In some MOCVD processes, either Nitrogen or Hydrogen is used at a pressure of about 15-30 psig. A mass flow controller (MFC) (not shown) can also be applied to the carrier gas inlet to primary bubbler 126. This source MFC ensures the flow with the vaporized/sublimated precursor is at a desired rate. In embodiments, a second MFC, called a dilution MFC, is supplied with the carrier gas only and directed to the outlets without mixing with the precursor material. In order to avoid condensation in the MFCs, they are heated, for example with heat exchangers. In one embodiment, input MFCs can be heated up to the temperature at least 5° C. higher than the temperature of the bubbler.

After picking up precursor molecules at the vapor pressure of the precursor material, the high concentration mixture can be directed to a concentration sensor (not shown) at the outlet of the primary bubbler 126. The concentration sensor can also be heated to prevent condensation. In one embodiment, the sublimator temperature is 55° C., its pressure controlled by a back pressure regulator is 1150 torr, and the temperature of the MFCs and Piezoelectric concentration sensor is 60° C.-65° C., then the performance of the concentration measurement will be higher than conventional systems. The table below shows accuracy and repeatability of the concentration measurement in the TrimethylIndium/Nitrogen and Cyclopentadienil Magnesium/Nitrogen binary mixtures at the sublimater temperature of 55° C. and its pressure of 1150 torr.

| | Vapor | Concen- | Relative | Relative |
|---|---|---|---|---|
| | Pressure | tration at | Piezocon | Piezocon |
| | at 55° C., | 1150 torr, | Accuracy, | Repeatability, |
| Precursor | torr | ppm | % | % |
| TrimethylIndium | 12.9 | 11220 | 1.36 | 0.18 |
| Cyclopentadienil- | 0.52 | 452 | 27.2 | 3.6 |
| Magnesium | | | | |

Comparing accuracy and repeatability between these results and those of the conventional system described previously, concentration measurement can be improved roughly 10 times for the Trimethyllndium/Nitrogen mixture and about 20 times for the Cyclopentadienil Magnesium/Nitrogen mixture. Overall repeatability of the delivery system after the dilution can be estimated as

δ=\sqrt{δ_{Piezo}²+δ_{MFC1}²+δ_{MFC2}²}

Primary bubbler 126 contains such precursor material in the liquid state and a mechanism for bubbling or sparging the carrier gas through the liquid precursor. Bubbling the carrier gas through the liquid precursor causes the carrier gas to collect some of the precursor material as vapor and/or liquid aerosol. This mixture of carrier gas, vapor, and/or liquid aerosol, referred to hereinafter as the precursor gas mixture, can be used for deposition in a CVD system. In one embodiment, primary bubbler 126 comprises a tank of liquid precursor material and a dip tube through which carrier gas from first input line 116 can be routed.

Primary bubbler 126 can be heated to a desired temperature such that the vapor pressure of the liquid precursor is known. Furthermore, primary bubbler 126 is sealed against ingress from ambient air, because primary bubbler 126 often contains pyrophoric materials. As such, when primary bubbler 126 is empty or must be replaced for any other reason, it may take significant time to safely remove and replace it.

Likewise, auxiliary bubbler 128 is configured to provide the precursor gas. Auxiliary bubbler 128 is similar to primary bubbler 126, but auxiliary bubbler 128 receives carrier gas input from fourth input line 122.

Primary bubbler 126 and auxiliary bubbler 128 provide precursor gas outputs via primary bubbler outlet line 130 and auxiliary bubbler outlet line 132, respectively. Primary bubbler outlet line 130 splits into two lines: low concentration primary bubbler outlet line 130L and high concentration primary bubbler outlet line 130H. Likewise, auxiliary bubbler outlet line 132 splits into two lines: low concentration auxiliary bubbler outlet line 132L and high concentration auxiliary bubbler outlet line 132H.

Low concentration output 134 receives carrier gas from second input line 118, low concentration primary bubbler outlet 130L, and low concentration auxiliary bubbler outlet 132L. Low concentration output 134 can include a mixer, in embodiments, to combine the outputs from these lines. Additionally or alternatively, in some embodiments low concentration output 134 can include an accumulator tank or hose.

Low concentration output 134 provides low concentrations of precursor gas in carrier gas for CVD processes. The concentration of precursor gas provided by low concentration output 134 is often significantly lower than the concentration of precursor gas provided at primary bubbler outlet line 130 or auxiliary bubbler outlet line 132. In order to generate the desired low concentration of precursor gas in carrier gas, second input line 118 can provide relatively large quantities of carrier gas to dilute the mixture provided by low concentration primary bubbler outlet 130L and low concentration auxiliary bubbler outlet 132L.

In the embodiment shown in FIG. 1, low concentration output 134 can be provided even if one of the bubblers (126, 128) is not providing any output. For example, if primary bubbler 126 is not providing any output to low concentration primary bubbler outlet line 130L, low concentration output 134 can nonetheless create a desired low concentration mixture by combining the gas from second carrier gas input line 118 and low concentration auxiliary bubbler outlet line 132L. Likewise, if auxiliary bubbler 128 is not providing any output to low concentration auxiliary bubbler outlet line 132L, low concentration output 134 can nonetheless create a desired low concentration mixture by combining the gas from second carrier gas input line 118 and low concentration primary bubbler outlet line 130L. Therefore, so long as one of the two bubblers (126, 128) is installed at any given time, low concentration output 134 can generate a desired concentration of precursor gas in carrier gas by adjusting the quantity of carrier gas provided by second carrier gas input line 118 at user interface 114.

High concentration output 136 provides relatively higher concentrations of precursor gas than those provided by low concentration output 134. The concentration of precursor gas within the carrier gas is still lower than the output of primary bubbler 126 and auxiliary bubbler 128. To generate the desired concentration of precursor gas in carrier gas, high concentration output 136 receives carrier gas from third input line 120, high concentration primary bubbler outlet 130H, and high concentration auxiliary bubbler outlet 132H. High concentration output 136 can include a mixer, in embodiments, to combine the outputs from these lines. Additionally or alternatively, in some embodiments high concentration output 136 can include an accumulator tank or hose.

As previously described with respect to low concentration output 134, high concentration output 136 can maintain a desired concentration output even when one of the bubblers (126, 128) is not providing any output. This can be accomplished for either output (134 or 136) by manually or automatically adjusting the quantity of carrier gas provided by second input line 118 or third input line 120, respectively.

System 110 therefore is capable of providing both high concentration and low concentration precursor gas mixtures, even when primary bubbler 126 or auxiliary bubbler 128 is removed from service. For example, if primary bubbler 126 is removed to be refilled or replaced, the desired precursor gas concentrations can still be provided by auxiliary bubbler 128 until such time as primary bubbler 126 is brought back online, and vice versa. This reduces or eliminates downtime associated with replacing bubblers in conventional systems.

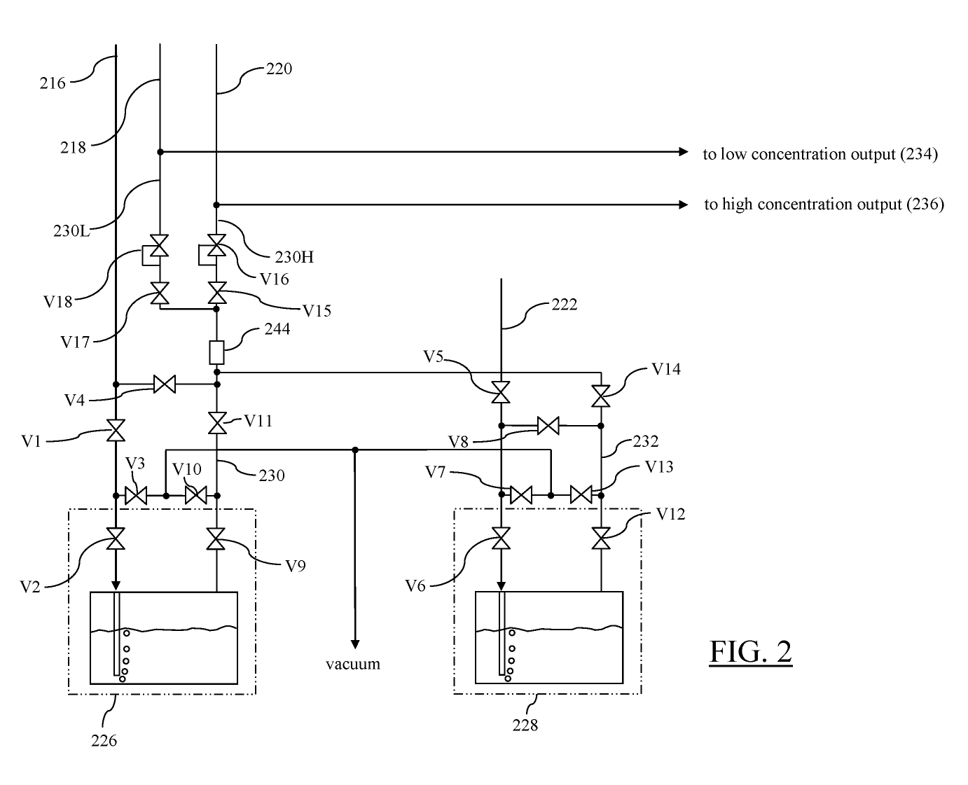

FIG. 2 is a more detailed view of one embodiment of piping system 210 within cutout 2 of FIG. 1. In particular, FIG. 2 depicts a series of valves V1-V12 that can be used with In alternative embodiments, various other piping systems 210 could be employed that would facilitate interchangeable delivery of precursor gas from primary bubbler 126 and auxiliary bubbler 128 of FIG. 1.

Piping system 210 of FIG. 2 includes several components similar to those previously depicted with respect to FIG. 1. Parts in FIG. 2 that are similar to those previously depicted in FIG. 1 have similar reference numerals, iterated by a factor of 100. For example, piping system 210 includes first input line 216, second input line 218, third input line 220, and fourth input line 222. First input line 216 is coupled to primary bubbler 226, and fourth input line 222 is coupled to auxiliary bubbler 228. Primary bubbler 226 outputs a concentrated mixture of precursor gas in carrier gas at primary bubbler outlet line 230, and auxiliary bubbler provides a concentrated mixture of precursor gas in carrier gas at auxiliary bubbler outlet line 232. Primary bubbler outlet line 230 splits into low concentration primary bubbler outlet line 230L and high concentration primary bubbler outlet line 230H. Auxiliary bubbler outlet line 232 splits into low concentration auxiliary bubbler outlet line 232L and high concentration auxiliary bubbler outlet line 232H.

In addition to those components shown in FIG. 2 that are similar to those previously described with respect to FIG. 1, FIG. 2 shows several structural features that facilitate the delivery of precursor gas from either or both of the bubblers 226 and 228. For example, in the embodiment shown in FIG. 2, valves V1-V18 are arranged to facilitate removal or replacement of one bubbler while high and low concentration outputs 236 and 234 are still provided.

Valves V1-V4 control the input to primary bubbler 226. Valve V1 is positioned along first input line 216. Second valve V2 is positioned at primary bubbler 226. A line towards a vacuum is connected to first input line 216 between first valve V1 and second valve V2, controlled by valve V3. The combination of valves V1-V3 permit for the line to be used to provide carrier gas to bubbler 226 (with valves V1 and V2 open but valve V3 closed), purged (with valves V1 and V2 closed but valve V3 open). Valve V4 can be opened or closed to operate a bypass line. By closing valve V1 or valves V2 and V3, and opening valve V4, carrier gas can bypass primary bubbler 226 altogether and be routed directly to be combined with the contents of the output lines 230 and 232.

Similar structures are provided for control of the input to auxiliary bubbler 228. Fifth valve V5 is positioned along fourth input line 222. Sixth valve V6 is positioned at auxiliary bubbler 228. A line towards a vacuum is connected to fourth input line 222 between fifth valve V5 and sixth valve V6, controlled by seventh valve V7. A bypass line to the output lines 230 and 232 is operated by valve V8. Valves V5-V8 can be controlled as previously described with respect to valves V1-V4, respectively, but to control the lines coupled to the input of auxiliary bubbler 228, rather than the lines coupled to the input of primary bubbler 226.

The outputs of primary bubbler 226 and auxiliary bubbler 228 are similarly controlled by a series of valves. While the inputs (i.e., the lines coupled to first carrier gas input 216 and fourth carrier gas inlet 222) are typically provided with inert gas, the outputs of the bubblers 226 and 228 can contain precursor material, which can be pyrophoric, toxic, or hazardous in some other way, depending upon the precursor used for any particular chemical vapor deposition process.

The outputs of primary bubbler 226 are controlled by valves V9-V11. Ninth valve V9 is provided at primary bubbler 226, and can be used to prevent egress of precursor material therefrom. Ninth valve V9 is similar to second valve V2, in that it is a part of primary bubbler 226. With ninth valve V9 open, the precursor gas mixture can flow to primary bubbler outlet line 230. In order to facilitate purging of primary bubbler outlet line 230, a vacuum line is coupled to primary bubbler outlet line 230 via tenth valve V10. As shown in FIG. 2, tenth valve V10 and third valve V3 connect first input line 216 and primary bubbler outlet line 230, respectively, to the same vacuum line. In alternative embodiments, separate vacuum lines could be used. Eleventh valve V11 is positioned along primary bubbler outlet line 230. Eleventh valve V11 can be opened when precursor gas mixture is provided by primary bubbler 226, and closed otherwise. When eleventh valve V11 is closed, a vacuum can be pulled on primary bubbler outlet line 230 via tenth valve V10, but the vacuum is fluidically separated from the low concentration output 234 and the high concentration output 236.

The outputs of auxiliary bubbler 228 are controlled by valves V12-V14, in a similar fashion to the controls previously described with respect to valves V9-V11. By selectively opening and closing valves V12-V14, precursor gas mixture can be provided by auxiliary bubbler 228, or vacuum can be applied to the auxiliary bubbler output line 232. Such vacuum can be used to facilitate removal or replacement of primary bubbler 226 and auxiliary bubbler 228 without exposing a pressurized line of hazardous precursor gas mixture to ambient atmosphere.

The embodiment shown in FIG. 2 includes a flowmeter 244. Flowmeter 244 can be, for example, a piezoelectric flow meter as described in U.S. Pat. No. 6,279,379 (filed Nov. 19, 1999), configured to determine the concentration of precursor gases within a flowing precursor gas mixture using time-of-flight measurements. The signal output by flowmeter 244 can include information relating to the flow rate and/or the concentration of precursor gases within the precursor mixture. Utilizing this information, a user can either manually or automatically control second input line 218 and third input line 220 in order to create high and low concentration outputs 236 and 234, as shown.

Fifteenth valve V15 and sixteenth valve V16 route precursor gas mixture towards the low concentration output 236. As shown in FIG. 2, the combined output of primary bubbler output line 230 and auxiliary bubbler output line 232 is present at the input to fifteenth valve V15. Fifteenth valve V15 can be variably adjustable to permit a desired quantity of precursor gas mixture through. Sixteenth valve V16 is a back pressure regulator valve that does not allow the output to reach a pressure that is above a desired threshold.

In embodiments, a concentration measurement device, such a piezoelectric concentration sensor, can be used to determine the mass flow of the dilution carrier at fifteenth valve V15 gas to insure that the concentration exiting the central source delivery system is accurate. In various embodiments, other temperature or concentration sensors can be positioned throughout the system to ensure that those aspects of the system are well-controlled.

The precursor gas mixture that passes through both variable fifteenth valve V15 and back pressure regulating sixteenth valve V16 can be augmented with additional carrier gas from third input line 220. Often, the precursor gas mixture provided by primary bubbler output line 230 and/or auxiliary bubbler output line 232 has a higher concentration of precursor gas than needed for deposition. Furthermore, excessive concentration of precursor gas in the lines can cause settling out or condensation, as described above. By routing in additional carrier gas from third input line 220 to dilute the precursor gas in the low concentration output 236 line, such unwanted phenomena can be avoided. Likewise, as described above with respect to FIG. 1, additional components such as a mixer (not shown) can be employed in the low concentration output 236 line in order to prevent settling out, stratification, or condensation, and/or convert liquid aerosol precursor to vapor precursor. In embodiments, the precursor gas mixture at low concentration output 236 can be sufficiently mixed and low-concentration that even at relatively low temperatures, such as 70° C., condensation will not occur.

Likewise, seventeenth valve V17 and eighteenth valve V18 route precursor gas mixture towards the low concentration output 234. Seventeenth valve V17 can be variably adjustable to permit a desired quantity of precursor gas mixture through. Eighteenth valve V18 is a back pressure regulator valve that does not allow the output to reach a pressure that is above a desired threshold. The precursor gas mixture that passes through both variable seventeenth valve V17 and back pressure regulating eighteenth valve V18 can be augmented with additional carrier gas from second input line 218.

In embodiments, more carrier gas is routed from second input line 218 than from third input line 220. More precursor gas mixture can also be routed through variable fifteenth valve V15 than variable sixteenth valve V16, in embodiments. Accordingly, the ratio of precursor gas to carrier gas can be higher in the low concentration output 236 than in the low concentration output 234.

As shown in FIG. 2, even in the absence of any output from primary bubbler 226, precursor gas mixture can be provided by auxiliary gas mixture 228. By closing valves V1, V2, V9, and V11, and by opening valves V3 and V10, the input and output lines to primary bubbler 226 can be purged even while auxiliary bubbler continues to provide precursor gas mixture at flowmeter 244. By then closing valves V3 and V10, and venting the input and output lines, primary bubbler 226 can be removed and replaced. The input and output lines to primary bubbler 226 can be vacuum-purged again, and then valves V1 and V2 reopened to provide carrier gas to the new or refilled primary bubbler 226, and valves V9 and V11 reopened to allow egress of precursor gas mixture to flowmeter 244.

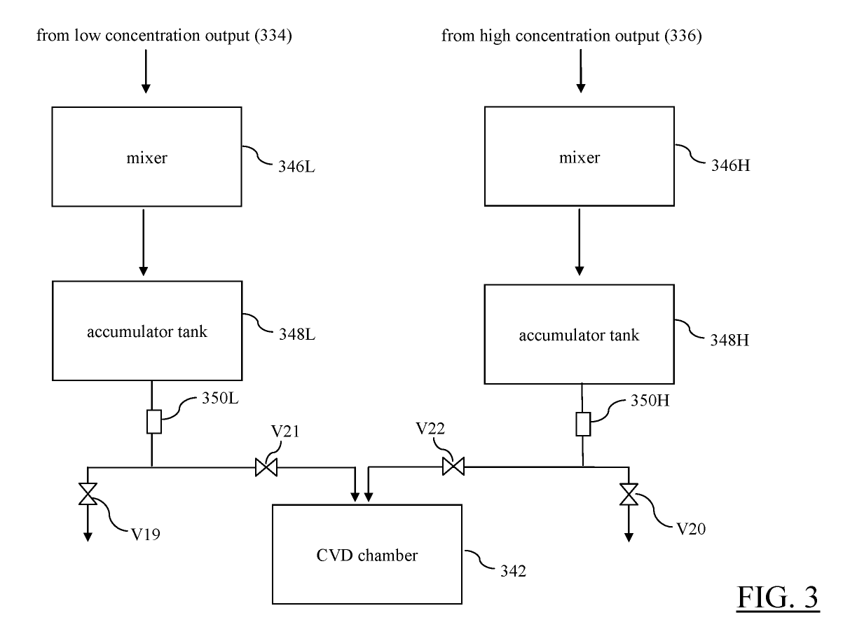

FIG. 3 depicts a system 300 for delivery of precursor gas material from a low concentration output 334 and a high concentration output 336 to a CVD chamber 342. In order to prevent stratification and increase homogeneity, a static mixer 346L is provided to mix gas from the low concentration output 334 and likewise a static mixer 346H is provided to mix gas from the high concentration output 336. The mixed gas is then provided to an accumulator tank (348L and 348H, respectively).

Gas mixture held in each of the accumulator tanks 348L, 348H can be vented via nineteenth valve V19 and twentieth valve V20, respectively. Such venting can be used when the pressure within the accumulator tanks 348L and 348H becomes too high, or when the CVD process is complete, for example. Alternatively, gas within accumulator tanks 348L, 348H can be provided to CVD chamber 342 via twenty-first valve V21 or twenty-second valve V22, respectively.

In embodiments, each of the valves V19-V22 can be variable valves, such that a desired flowrate can be established to each corresponding outlet. Furthermore, flowmeters 350L and 350H can be used to determine the flow rate and/or the precursor gas concentration from each accumulator tank 348L and 348H, respectively. Information sensed by flowmeters 350L and 350H can therefore be used to modify the setting of each of the valves V19-V21.

Combining the elements of FIGS. 1-3, a system is provided in which a precursor generation source, precursor gas conditioning, and precursor gas delivery can be accomplished continuously. Downtime associated with removal or replacement of a bubbler or other precursor gas source can be obviated. Furthermore, because precursor gas mixture is generated that has a relatively low concentration, it is not necessary to position the bubbler or other precursor gas source directly on the reactor chamber or tool itself because the precursor gas mixture is not so prone to condensation or stratification. The ability to position precursor gas sources further from the reactor housing itself facilitates a smaller tool foot-print, and therefore tighter cleanliness requirements for semiconductor applications can be more easily met, as well as facilitating re-layout of the tool for serviceability. In embodiments, the system can facilitate scaling, or addition of more precursor to reactors. By enabling accumulation of multiple concentrations of precursor gas in carrier gas, reduced venting of precursor gas mixes is accomplished, and an improvement in run-to-run and tool-to-tool matching due to controlled and stable delivery of flux is possible.

In embodiments, relatively more or fewer precursor gas sources and concentration outputs can be provided. In one alternative embodiment, a third bubbler can be provided, which is also coupled to a carrier gas inlet. The outlet of the third bubbler can be comingled with the outputs of the other two precursor gas sources prior to splitting into low and high concentration output lines. Alternatively or additionally, a third concentration output line can be generated, with a separate carrier gas input line to facilitate mixing to a desired concentration, and an associated mixer, accumulator, and flowmeter can be provided for the third output line. Those of skill in the art will recognize that, with any number of precursor gas sources greater than 1, and with any number of output lines equal to or greater than 1, the systems described explicitly herein can be modified to accomplish the benefits described above.

Various embodiments of systems, devices and methods have been described herein. These embodiments are given only by way of example and are not intended to limit the scope of the invention. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the invention.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112(f) of 35 U.S.C. are not to be invoked unless the specific terms “means for” or “step for” are recited in a claim.

I claim:

1. A system for providing a continuous source of a precursor gas mixture having a desired concentration, the system comprising:
a user interface comprising a plurality of carrier gas inputs;
a primary precursor gas source configured to receive a carrier gas from one of the plurality of carrier gas inputs and produce a primary precursor gas mixture;
an auxiliary precursor gas source configured to receive a carrier gas from one of the plurality of carrier gas inputs and produce an auxiliary precursor gas mixture; and
an output configured to receive a continuous flow of the precursor gas mixture by combining:
at least a portion of the primary precursor gas mixture;
at least a portion of the auxiliary precursor gas mixture; and
a carrier gas from at least one of the plurality of carrier gas inputs.

2. The system of claim 1, and further comprising a second output, the second output configured to combine:
at least a portion of the primary precursor gas mixture;
at least a portion of the auxiliary precursor gas mixture; and
a carrier gas from at least one of the plurality of carrier gas inputs,
and wherein the second output produces a lower concentration of precursor gas mixture in carrier gas than the output.

3. The system of claim 1, wherein each of the plurality of carrier gas inputs are automated to provide a quantity of carrier gas to each of the primary precursor gas source, the auxiliary precursor gas source, and the output, such that the concentration of precursor gas in carrier gas at the output is maintained at a predetermined level.

4. The system of claim 3, wherein the predetermined level is low enough that the precursor gas will not condense or stratify at 70° C.

5. The system of claim 3, wherein the primary precursor gas source and the auxiliary precursor gas source as arranged remote from a chemical vapor deposition tool.

6. The system of claim 5, further comprising a static mixer arranged between the output and the chemical vapor deposition tool.

7. The system of claim 5, further comprising an accumulator arranged between the output and the chemical vapor deposition tool.

8. The system of claim 1, further comprising a vacuum source.

9. The system of claim 8, wherein the vacuum source can be selectively coupled to one or more of:
an inlet of the primary precursor gas source;
an outlet of the primary precursor gas source;
an inlet of the auxiliary precursor gas source; and
an outlet of the auxiliary precursor gas source.

10. The system of claim 9, wherein the primary precursor gas source and the auxiliary precursor gas source each include an inlet valve and an outlet valve, positioned at the inlet and outlet, respectively, of the primary precursor gas source and the auxiliary precursor gas source.

11. The system of claim 8, further comprising a flowmeter configured to measure the concentration and flow rate of a precursor gas mixture at the output.

12. The system of claim 11, further comprising:
a first shutoff valve arranged between the output and the outlet of the primary precursor gas source; and
a second shutoff valve arranged between the output and the outlet of the auxiliary precursor gas source.

13. The system of claim 1, wherein the primary precursor gas source and the auxiliary precursor gas source each comprise a bubbler.

14. A method for continuous operation of a chemical vapor deposition system, the method comprising:
providing a carrier gas at a first user input and routing it to the inlet of a primary precursor gas source to generate a precursor gas mixture at an outlet of the primary precursor gas source;
providing a carrier gas at a second user input and routing it to the inlet of an auxiliary precursor gas source to generate a precursor gas mixture at an outlet of the auxiliary precursor gas source;
combining the precursor gas mixture of the primary precursor gas source and the precursor gas mixture of the auxiliary gas source to form a combined precursor gas mixture;
mixing at least a portion of the combined precursor gas mixture with a carrier gas from a third user input to form a diluted precursor gas mixture that has a sufficiently low concentration that the precursor gas is fully soluble in the carrier gas above a temperature; and
routing the diluted precursor gas mixture, at or above the temperature, to a remote chemical vapor deposition tool.

15. The method of claim 14, further comprising mixing the diluted precursor gas mixture at a static mixer.

16. The method of claim 14, further comprising holding the diluted precursor gas mixture at an accumulator.

17. The method of claim 14, further comprising mixing another portion of the combined precursor gas mixture with a carrier gas from a fourth user input to form a second diluted precursor gas mixture, the second diluted precursor gas mixture having a concentration different from that of the diluted precursor gas mixture.

18. The method of claim 14, wherein:
the primary precursor gas source can be isolated and removed and the first user input can be shut off, such that the combined precursor gas mixture includes only the precursor gas mixture at an outlet of the auxiliary precursor gas source; and alternatively
the auxiliary precursor gas source can be isolated and removed and the second user input can be shut off, such that the combined precursor gas mixture includes only the precursor gas mixture at an outlet of the primary precursor gas source.

19. The method of claim 18, wherein isolating and removing the primary precursor gas source comprises:
vacuum-purging an output line positioned between a valve at the outlet of the primary precursor gas source and a valve fluidically between the primary precursor gas source and the combined precursor gas mixture;
venting the output line;
removing and replacing the primary precursor gas source;
vacuum-purging the output line and the an input line positioned between a valve at the inlet of the primary precursor gas source and a valve fluidically between the primary precursor gas source and the first user input;
routing the carrier gas from the first user input to the primary precursor gas source; and
routing the precursor gas mixture from the outlet of the primary precursor gas source to the combined precursor gas mixture.

20. The method of claim 18, wherein isolating and removing the auxiliary precursor gas source comprises:
vacuum-purging an output line positioned between a valve at the outlet of the auxiliary precursor gas source and a valve fluidically between the auxiliary precursor gas source and the combined precursor gas mixture;
venting the output line;
removing and replacing the auxiliary precursor gas source;
vacuum-purging the output line and the an input line positioned between a valve at the inlet of the auxiliary precursor gas source and a valve fluidically between the auxiliary precursor gas source and the first user input;
routing the carrier gas from the first user input to the auxiliary precursor gas source; and
routing the precursor gas mixture from the outlet of the auxiliary precursor gas source to the combined precursor gas mixture.
